(19) United States
(12) Patent Application Publication
(10) Pub. No.: US 2014/0141613 A1
(43) Pub. Date: May 22, 2014

(54) PROCESS FOR POLISHING A SEMICONDUCTOR WAFER, COMPRISING THE SIMULTANEOUS POLISHING OF A FRONT SIDE AND OF A REVERSE SIDE OF A SUBSTRATE WAFER

(71) Applicant: Siltronic AG, Munich (DE)

(72) Inventors: Alexander Heilmaier, Haiming (DE); Leszek Mistur, Burghausen (DE); Klaus Roettger, Bachmehring (DE); Makoto Tabata, Kakamigahara (JP)

(73) Assignee: Siltronic AG, Munich (DE)

(21) Appl. No.: 14/083,486

(22) Filed: Nov. 19, 2013

(30) Foreign Application Priority Data
Nov. 20, 2012 (DE) 10 2012 221 217.5
Sep. 19, 2013 (DE) 10 2013 218 880.3

(51) Int. Cl. H01L 21/02

(52) U.S. Cl. CPC H01L 21/02024
USPC 438/693

(57) ABSTRACT

A process for polishing a semiconductor wafer includes simultaneous polishing of a front side and of a reverse side of a substrate wafer in the presence of polishing medium so as to achieve material removal from the front side and the reverse side of the substrate wafer. The simultaneous polishing includes a first step and a second step. A speed of material removal in the first step is higher than in the second step. The first step includes the use of a first polishing slurry as a polishing medium and the second step includes a second polishing slurry as the polishing medium. The second polishing slurry differs from the first polishing slurry at least in that the second polishing slurry comprises a polymeric additive.

### CROSS REFERENCE TO RELATED APPLICATIONS

This application claims priority from German Patent Application No. DE 10 2012 221 217.5, filed Nov. 20, 2012 and German Patent Application No. DE 10 2013 218 880.3, filed Sep. 19, 2013, both of which are hereby incorporated by reference herein in their entireties.

### FIELD

The invention provides a process for polishing a semiconductor wafer, comprising the simultaneous polishing of a front side and of a reverse side of a substrate wafer.

### BACKGROUND

The simultaneous polishing of both side faces of a substrate wafer is also called double-sided polishing, abbreviated hereinafter to DSP.

Semiconductor wafers, especially semiconductor wafers made from monocrystalline silicon, are cut from crystals and subjected to a series of processing steps, which frequently also include at least one DSP. Before the DSP is employed, the semiconductor wafer goes through a preparatory processing operation, which may comprise especially cleaning steps, shaping steps and surface-improving steps. Such steps include, for example, the lapping and/or grinding of the side faces, the etching of the semiconductor wafer and the rounding and polishing of the edge of the semiconductor wafer. A semiconductor wafer which is intended for DSP and has received such preparatory processing is referred to hereinafter as substrate wafer.

The aim of DSP is typically to convert the semiconductor wafer to a state with polished front and reverse sides, the intention being that the two side faces have maximum flatness and are parallel to one another to a maximum degree. “Edge roll-off” refers to the case when the thickness of the polished semiconductor wafer decreases significantly in a region immediately in front of the rounded and polished edge of the semiconductor wafer. Parameters which describe the geometry of the edge roll-off in quantitative terms are, in particular, ESFQR and ZDD. After polishing by means of DSP, an edge roll-off can frequently be observed, which is expressed by ESFQR and ZDD values having comparatively large magnitudes.

US 2011/0130073 A1 states that there are advantages to dividing the DSP of a semiconductor wafer into two steps, and to using a polishing slurry which produces comparatively high material removal in the first step, and to switching to a polishing slurry which produces comparatively low material removal in the second step. This procedure shortens the duration of the DSP without influencing the flatness and surface roughness of the semiconductor wafer.

### SUMMARY

In an embodiment, the present invention provides a process for polishing a semiconductor wafer includes simultaneous polishing of a front side and of a reverse side of a substrate wafer in the presence of polishing medium so as to achieve material removal from the front side and the reverse side of the substrate wafer. The simultaneous polishing includes a first step and a second step. A speed of material removal in the first step is higher than in the second step. The first step includes the use of a first polishing slurry as a polishing medium and the second step includes a second polishing slurry as the polishing medium. The second polishing slurry differs from the first polishing slurry at least in that the second polishing slurry comprises a polymeric additive.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 is a diagram in which the polishing pressure P is plotted against time t.

FIG. 2 shows the relative thickness th of a semiconductor wafer B polished in accordance with the invention after completion of DSP against the diameter d of the semiconductor wafer.

FIG. 3 shows the relative thickness th of a semiconductor wafer V polished not in accordance with the invention after completion of DSP against the diameter d of the semiconductor wafer.

### DETAILED DESCRIPTION

An aspect of the present invention is to indicate a process by which a lower edge roll-off on completion of DSP can also be achieved over and above these advantages.

In an embodiment, the present invention provides a process for polishing a semiconductor wafer, comprising the simultaneous polishing of a front side and of a reverse side of a substrate wafer in the presence of polishing medium and with achievement of material removal from the front side and the reverse side of the substrate wafer, divided into a first and a second step, the speed of material removal in the first step being higher than in the second step, wherein a first polishing slurry is used as the polishing medium in the first step and a second polishing slurry as the polishing medium in the second step, and the second polishing slurry differs from the first polishing slurry at least in that the second polishing slurry comprises a polymeric additive.

The first and second polishing slurries may differ not just in relation to the presence of the polymeric additive, but also with regard to other components. With regard to matching components, differences may exist in the concentration. Chemical and physical properties such as pH may be the same or different.

The first and second steps are performed in immediate succession and without changing the polishing machine.

The polishing machine comprises two polishing plates each covered with a polishing pad, and comprises at least one carrier which is arranged between the polishing pads and has a recess into which the substrate wafer for polishing is placed. Suitable polishing machines are available on the market.

The speed of material removal in the first step is preferably not less than 0.4 μm/min and not more than 1.0 μm/min, and in the second step is preferably not less than 0.15 μm/min and not more than 0.5 μm/min.

The material removal per unit side area in the first step is preferably not less than 4 μm and not more than 15 μm, and in the second step is preferably not less than 0.5 μm and not more than 2 μm.

Preferably, material removal is brought about, the effect of which is that, after performance of the process according to the invention, the difference between the averaged thickness of the polished semiconductor wafer and the averaged thickness of the carrier is negative or positive.

During the first and second steps, polishing can be effected with the same polishing pressure or with different polishing pressures.

In contrast to the first step, the second polishing slurry used in the second step comprises a polymeric additive. Useful polymeric additives preferably include one or more compounds which are mentioned by name in US 2011/0217845 A1 as nonionic active agent or as water-soluble polymer.

Examples are one or more of the following compounds: polyoxyethylene, polyethylene glycol, polyoxypropylene, polyoxybutylene, polyoxyethylene-polyoxypropylene glycol, polyoxyethylene-polyoxybutylene glycol, and water-soluble cellulose derivatives.

The concentration of the polymeric additive in the second polishing slurry is preferably not less than 0.001% by weight and not more than 0.1% by weight.

The second step can be initiated by supplying a polishing slurry comprising the polymeric additive as a replacement for the first polishing slurry. Alternatively, the second polishing slurry supplied comprises a mixture of the first polishing slurry and a polymeric additive.

The first and second polishing slurries comprise at least one abrasive active ingredient, preferably colloidally distributed silicon dioxide. The concentration of the abrasive active ingredient may be the same or different.

The first and second polishing slurries preferably have a pH of not less than 10 and not more than 13, and comprise at least one of the following alkaline compounds: sodium carbonate, potassium carbonate, sodium hydroxide, potassium hydroxide, ammonium hydroxide and tetramethylammonium hydroxide. The concentration and nature of the alkaline compound may be the same or different.

The substrate wafer to be polished is preferably a semiconductor wafer consisting essentially of monocrystalline silicon. After DSP according to the invention of such a substrate wafer, the edge geometry of the polished semiconductor wafer expressed as the ESFQRmax, is preferably not more than 40 nm. ESFQRmax is the ESFQR of that edge sector of the semiconductor wafer in which the highest edge roll-off is measured.

The substrate wafer preferably has a diameter of at least 200 mm, more preferably a diameter of 300 mm or 450 mm.

The semiconductor wafer polished in accordance with the invention can be subjected to at least one further polishing operation, preferably to single-sided polishing of the front side. The front side is that side face intended as the substrate for formation of electronic components.

### EXAMPLE AND COMPARATIVE EXAMPLE

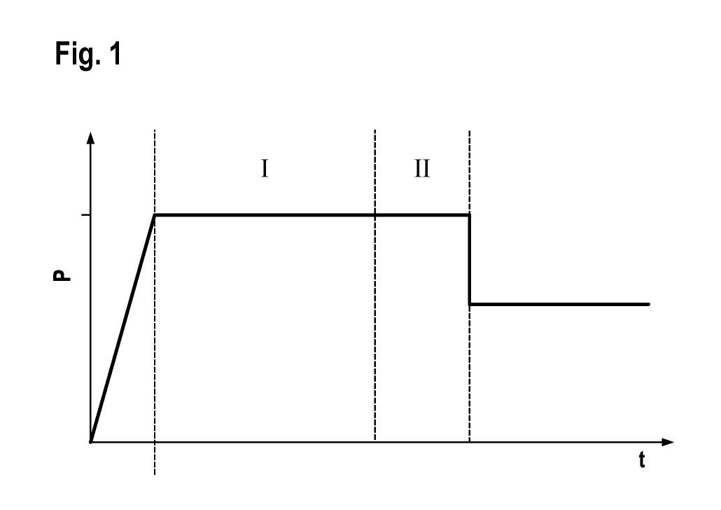

Substrate wafers of monocrystalline silicon having a diameter of 300 mm were subjected to the process according to the invention. The semiconductor wafers were polished on a Wolters AC2000 DSP machine. The polishing pressure P was altered during the DSP as shown in FIG. 1. After a start phase with rising polishing pressure, the substrate wafer was polished at constant polishing pressure together with further substrate wafers. Subsequently, the polishing pressure was lowered to stop the polishing. The phase with constant polishing pressure was subdivided into a first phase I and a second phase II. During the first phase I, a polishing medium having the properties of the first polishing slurry was supplied. During the second phase II, in place of the first polishing medium, a polishing medium having the properties of the second polishing slurry was supplied.

For comparison, equivalent substrate wafers were polished in the same way, with the exception of the subdivision of the phase with constant polishing pressure. During this phase, only the first polishing slurry was used.

The table which follows shows typical values for the edge geometry of the polished semiconductor wafers for a semiconductor wafer B polished in accordance with the invention and a semiconductor wafer V polished not in accordance with the invention.

TABLE

| | ESFQRmax | ZDD at radius = 148 mm |
|---|---|---|
| | [μm] | [nm/mm2] |
| B | 0.035 | −10 |
| V | 0.045 | −12 |

The magnitudes of the highest edge roll-off measured (ESFQRmax) and of the second derivative of the edge roll-off curve (ZDD) are much smaller in the case of the semiconductor wafer polished in accordance with the invention.

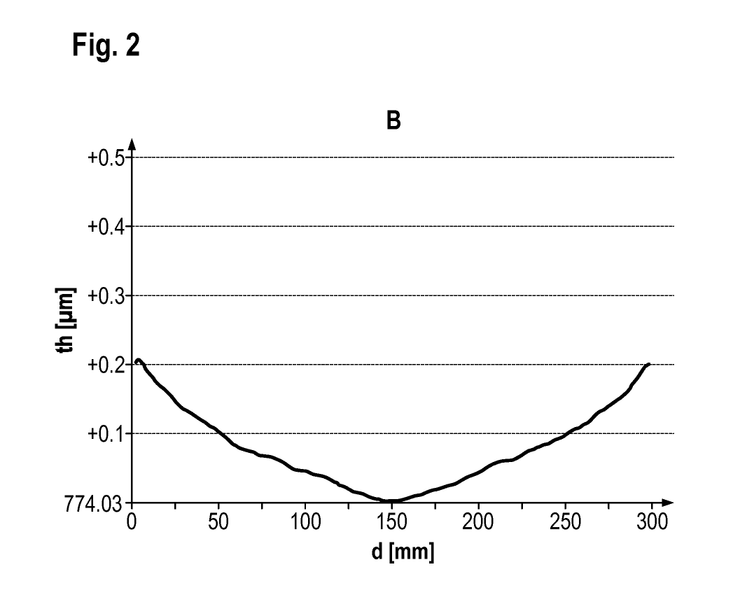

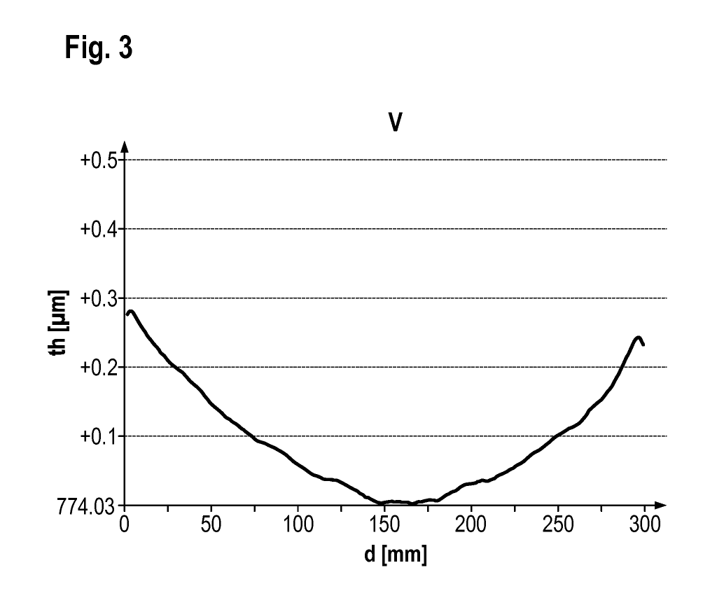

The advantage of the process according to the invention is also shown by a comparison of FIG. 2 and FIG. 3. The relative thickness th in the edge region changes much less in the case of a semiconductor wafer B polished in accordance with the invention than in the case of a semiconductor wafer V polished not in accordance with the invention.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A process for polishing a semiconductor wafer comprising:
simultaneous polishing of a front side and of a reverse side of a substrate wafer in the presence of polishing medium so as to achieve material removal from the front side and the reverse side of the substrate wafer, the simultaneous polishing including a first step and a second step, a speed of material removal in the first step being higher than in the second step, wherein the first step includes the use of a first polishing slurry as the polishing medium and the second step includes a second polishing slurry as the polishing medium, and wherein the second polishing slurry differs from the first polishing slurry at least in that the second polishing slurry comprises a polymeric additive.

2. The process as recited in claim 1, wherein the speed of material removal in the first step is not less than 0.4 μm/min and not more than 1.0 μm/min, and the speed of material removal in the second step is not less than 0.15 μm/min and not more than 0.5 μm/min.

3. The process as recited in claim 1, wherein the material removal per unit side area in the first step is not less than 4 μm and not more than 15 μm, and the material removal per unit side area in the second step is not less than 0.5 μm and not more than 2.0 μm.

4. The process as recited in claim 2, wherein the material removal per unit side area in the first step is not less than 4 μm and not more than 15 μm, and the material removal per unit side area in the second step is not less than 0.5 μm and not more than 2.0 μm.

5. The process as recited in claim 1, wherein an edge roll-off of the polished semiconductor wafer, expressed as ESFQRmax, is not more than 40 nm.

6. The process as recited in claim 2, wherein an edge roll-off of the polished semiconductor wafer, expressed as ESFQRmax, is not more than 40 nm.

7. The process as recited in claim 3, wherein an edge roll-off of the polished semiconductor wafer, expressed as ESFQRmax, is not more than 40 nm.
